(19) United States
(12) Patent Application Publication
(10) Pub. No.: US 2026/0291169 A1
(43) Pub. Date: Sep. 24, 2026

(54) Heat Transfer Apparatus with Multi-Directional Heat Flow

(71) Applicants: Hamamatsu Photonics K.K., Shizuoka (JP); Energetiq Technology, Inc., Wilmington, MA (US)

(72) Inventor: Craig M. Schiller, Arlington, MA (US)

(73) Assignees: Hamamatsu Photonics K.K., Shizuoka (JP); Energetiq Technology, Inc., Wilmington, MA (US)

(21) Appl. No.: 19/087,479

(22) Filed: Mar. 22, 2025

(51) Int. Cl. H01S 5/024

(52) U.S. Cl. CPC H01S 5/02476; H01S 5/02415

(57) ABSTRACT

A bi-directional heat transfer apparatus comprises a heat spreader configured to attach to a device or apparatus. A plurality of thermoelectric coolers is mounted in thermal contact with a plurality of different surfaces of the heat spreader. A respective one of the plurality of fan-cooled heat sinks is mounted in thermal contact with a respective one of the plurality of thermoelectric coolers so that each of the respective ones of the plurality of fan-cooled heat sinks removes heat by convection cooling in a respective one of a plurality of directions.

The section headings used herein are for organizational purposes only and should not be construed as limiting the subject matter described in the present application in any way.

### INTRODUCTION

Laser technology has continuously evolved since the first demonstration of the laser in 1960. In particular, semiconductor laser technology has evolved at a remarkably rapid pace and now can generate high laser power over a wide wavelength range. It has become increasingly difficult to dissipate the waste heat power in modern high power semiconductor lasers, given their electrical-to-optical conversion efficiency, their relatively small size, and their high optical power generating capability. Controlling heat dissipation is critical as the laser emission wavelength of semiconductor lasers is typically strongly dependent on temperature. Also, semiconductor lasers are easily damaged at high operating temperatures.

One particular application of high-power semiconductor lasers is laser-driven light sources. These light sources need to dissipate large amounts of heat. Numerous commercial and academic applications have a need for high brightness broadband light to contain a substantial flux in the ultra-violet (UV) region of the spectrum. For example, broadband UV light is needed for numerous industrial applications, including metrology, accelerated testing, photoresist, defect inspection, and microscopy. Other applications for broadband UV light include microscopy, spectroscopy, areal imaging, and blank mask inspection. These and other applications require UV sources with high brightness, high reliability, small physical size, low fixed cost, low operating cost, and low complexity from these critical sources of ultraviolet photons.

### SUMMARY

A multi-directional heat transfer apparatus includes a heat spreader with a thermally conductive device platform configured to mount the device to be temperature controlled. In some embodiments, the heat transfer apparatus is a heat pipe. For example, the heat spreader can be formed of copper. In some embodiments, the heat spreader comprises a thermally conductive heat spreading block. The heat spreader can comprise a graphene or metallic layer positioned adjacent to the device to be cooled. The device can be a laser, such as a semiconductor laser. In one specific embodiment, the device is a fiber coupled diode laser.

A first thermoelectric cooler is mounted in thermal contact with a first surface of the heat spreader and a first fan-cooled heat sink is mounted in thermal contact with the first thermoelectric cooler. The first fan-cooled heat sink is configured to remove heat in a first direction by forced air cooling. A second thermoelectric cooler is mounted in thermal contact with a second surface of the heat spreader and a second fan-cooled heat sink is mounted in thermal contact with the second thermoelectric cooler. The second fan-cooled heat sink is configured to remove heat in a second direction. In some embodiments, the second direction is non-collinear with the first direction. In one embodiment, the second direction of convection cooling is 90 degrees from the first direction of convection cooling. The first and second fan-cooled heat sinks can be each configured to either push air into the heat spreader or to pull air away from the heat spreader. The first and second thermoelectric coolers can be a plurality of thermoelectric coolers, where each of the plurality of thermoelectric coolers are mounted in thermal contact with a different surface of the heat spreader.

In some embodiments, at least one of the first and second thermoelectric coolers comprises a thermally conductive ceramic material configured to mount to the first surface of the heat spreader. A high-thermal-conductivity metallic material can be used. In other embodiments, at least one of the first and second thermoelectric coolers is mounted to a respective one of the first and second surfaces of the heat spreader with a graphene polymer or other non-metallic matrix composite material.

In some embodiments, an interface between the heat spreader and at least one of the first and second thermoelectric coolers can be configured so that the value of the areal thermal resistance (also known as R value) ranges from 0.01 to 0.10 cm² K/W (10⁻⁶ m² K/W to 10⁻⁵ m² K/W).

Also, in some embodiments, the thermal contact resistance between the heat spreader and at least one of the first and second thermoelectric coolers is established with a metallic foil. In other embodiments, the thermal contact resistance between the heat spreader and at least one of the first and second thermoelectric coolers is established with indium heat springs.

A heat transfer apparatus comprises a heat spreader configured to attach to a device or apparatus. A plurality of thermoelectric coolers is mounted in thermal contact with the heat spreader such that each thermoelectric cooler is in thermal contact with a different surface of the heat spreader. A respective one of a plurality of fan-cooled heat sinks is mounted in thermal contact with a respective one of the plurality of thermoelectric coolers. The plurality of fan-cooled heat sinks is configured such that each of the respective ones of the plurality of fan-cooled heat sinks removes heat by active (forced air) convective cooling or natural convection in a respective one of a plurality of non-collinear directions.

A method of cooling a device or apparatus includes mounting the device or apparatus on a heat spreader. A first surface of the heat spreader is thermoelectrically cooled. The thermoelectrically cooled first surface of the heat spreader is forced air cooled in a first heat flow direction. The second surface of the heat spreader is thermoelectrically cooled. The thermoelectrically cooled second surface of the heat spreader is forced air cooled in a second heat flow direction that can be linear or non-collinear with the first heat flow direction. In one embodiment, the second heat flow direction is 90 degrees from the first heat flow direction. In various embodiments, the forced air cooling of the first and second surfaces of the heat spreader comprises flowing air into or away from the heat spreader.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings described below are for illustration purposes only. The drawings are not necessarily to scale; emphasis is instead generally being placed upon illustrating principles of the teaching. The drawings are not intended to limit the scope of the Applicant's teaching in any way.

FIG. 1 illustrates a side view of a known heat transfer apparatus for controlling the temperature of a device or apparatus.

FIG. 2 illustrates a side view of a multi-directional heat transfer apparatus for controlling the temperature of a device or apparatus according to the present teaching.

FIG. 3 illustrates the results of a finite-element analysis of the temperature gradient as a function of distance into a copper heat spreader during the operation of a laser as it is cooled by the heat transfer apparatus described in connection with FIG. 2.

FIG. 4 illustrates experimental thermal performance data taken for the heat transfer apparatus described in connection with FIG. 2 with a heat load simulating the waste heat from a laser device operating during a testing period.

FIG. 5A illustrates a perspective view of a multi-directional heat transfer apparatus according to the present teaching that includes a heat transfer apparatus in both a horizontal linear configuration and a vertical linear configuration for controlling the temperature of a device or apparatus according to the present teaching.

FIG. 5B illustrates a perspective view of a multi-directional heat transfer apparatus according to the present teaching that includes a linear heat transfer apparatus arranged in a hexagonal configuration for controlling the temperature of a device or apparatus according to the present teaching.

### DESCRIPTION OF VARIOUS EMBODIMENTS

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications, and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the method of the present teaching can be performed in any order and/or simultaneously as long as the teaching remains operable. Furthermore, it should be understood that the apparatus and method of the present teaching can include any number or all of the described embodiments as long as the teaching remains operable.

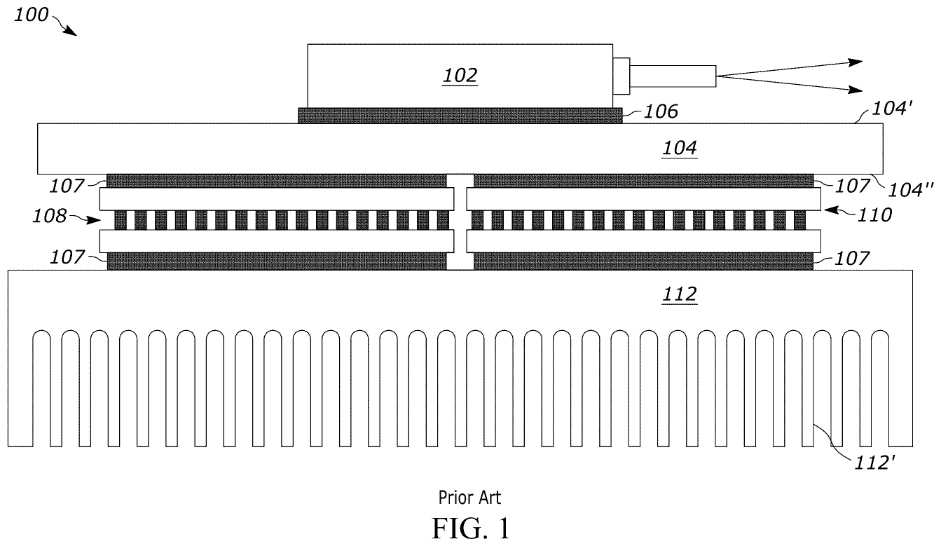

FIG. 1 illustrates a side view of a known heat transfer apparatus 100 for controlling the temperature of a device 102 or apparatus. The heat transfer apparatus 100 is configured in a vertical configuration with the device 102 to be cooled on the top surface. In the figure shown, the device 102 to be cooled is shown as a laser, but such known heat transfer apparatus is used to cool a variety of devices such as CPUs, sensors, and high-power electronic switching devices. Heat transfer apparatus according to the present teaching also applies to cooling a variety of optical and electrical devices.

The heat transfer apparatus 100 also includes a heat spreader 104 on the top surface, which is a thermally conductive device platform. The device 102 is positioned on the hot side 104′ of the heat spreader 104. The heat spreader 104 is made of a high thermal conductivity material. Common high thermal conductivity materials used in heat spreaders are aluminum and copper or some hybrid of these materials. Aluminum is lightweight, inexpensive, and has good thermal conductivity. Copper has higher thermal conductivity than aluminum but is heavier and more expensive. The device 102 can be attached to the heat spreader 104 with a thermally conductive interface material 106.

A first 108 and second Thermoelectric Cooler (TEC) 110 are positioned on the cold side 104″ of the heat spreader 104, which is furthest away from the device 102. Device 102 is the source of heat and contacts the hotter side of the heat spreader 104′ through thermal interface material 106. The TECs 108, 110 contact the heat spreader through thermally conductive interface material 107, which may be formed of different material from thermally conductive interface material 106. The first and second thermoelectric coolers 108, 110 are also known as Peltier coolers because they transfer heat using the Peltier effect, which occurs when an electric current passes through two dissimilar conductors, creating a temperature difference. Thermoelectric coolers are solid-state devices that are relatively small, but less efficient than traditional compressor-based cooling systems. They are well suited for cooling semiconductor lasers.

In operation, the first and second thermoelectric coolers 108, 110 absorb heat from the device 102 and then release the heat to a heat sink 112 and the surrounding area. Heat absorption occurs at the cold side 104″ junction in contact with the heat spreader 104, which is furthest away from the device 102. Heat rejection occurs at a hot side junction of the TECs 108 110 in contact with the heat sink 112, where heat is released to the environment. There is continuous cooling during operation of the thermoelectric coolers 108, 110 where heat continues to move from the cold side junction to the hot side junction, creating a cooling effect.

A conventional heat sink 112 with cooling fins 112′ is positioned at the hot side of the first and second thermoelectric coolers 108, 110 furthest away from the heat spreader 104. The heat sink 112 contacts the hot side of the TECs 108, 110 through thermal interface material 107. The conventional heat sink 112 is a passive thermal management device configured to dissipate heat generated by the device 102 and transferred through the first and second thermoelectric coolers 108, 110 into the surrounding environment. The cooling fins 112′ are typically formed by machining or other means directly from a single block of a thermally conductive material, such as aluminum or copper. A single block of high thermal conductivity material is used so that there is minimal thermal resistance between the base and the fins 112′. The cooling fins 112′ enhance the heat dissipation by increasing the surface area to increase convective cooling. Such cooling fins 112′ greatly increase the surface area of the heat sink, which allows more heat to be transferred to the air by convection, thereby enhancing cooling efficiency caused by convection cooling. The conventional passive heat sink relies on natural convection. However, other known heat sinks include a fan that improves air flow to provide active cooling.

Known heat transfer apparatuses, such as the apparatus 100 described in connection with FIG. 1 for controlling the temperature of a device have relatively short heat leakage paths from the hot side of the thermoelectric coolers to the device. This heat leakage is an additional load on these configurations of thermoelectric coolers and results in such a cooling apparatus being very susceptible to “thermal runaway,” a condition where increasing current flow through the TECs 108, 110 increases the cold side temperature. Consequently, these known heat transfer apparatus have relatively low thermal cooling efficiency that is insufficient for many high performance laser and electronic devices.

The present teaching relates to a high-performance multi-directional heat transfer apparatus, similar to heat pipes and other heat transfer apparatus that include a heat spreader comprising a thermally conductive device platform to mount the device to be temperature controlled. A first thermoelectric cooler is mounted in thermal contact with a first surface of a heat spreader block. A first fan-cooled heat sink is mounted in thermal contact with the first thermoelectric cooler, and is configured to remove heat in a first direction by convection cooling. A second thermoelectric cooler is mounted in thermal contact with a second surface of the heat spreader block. A second fan-cooled heat sink is mounted in thermal contact with the second thermoelectric cooler and is configured to remove heat in a second direction.

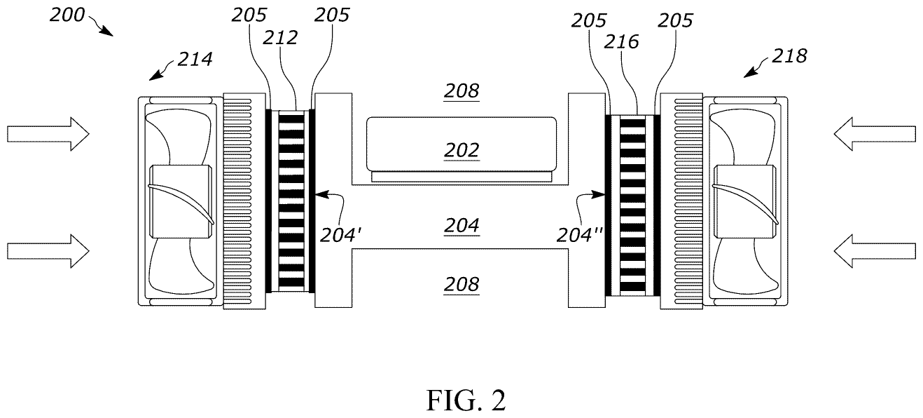

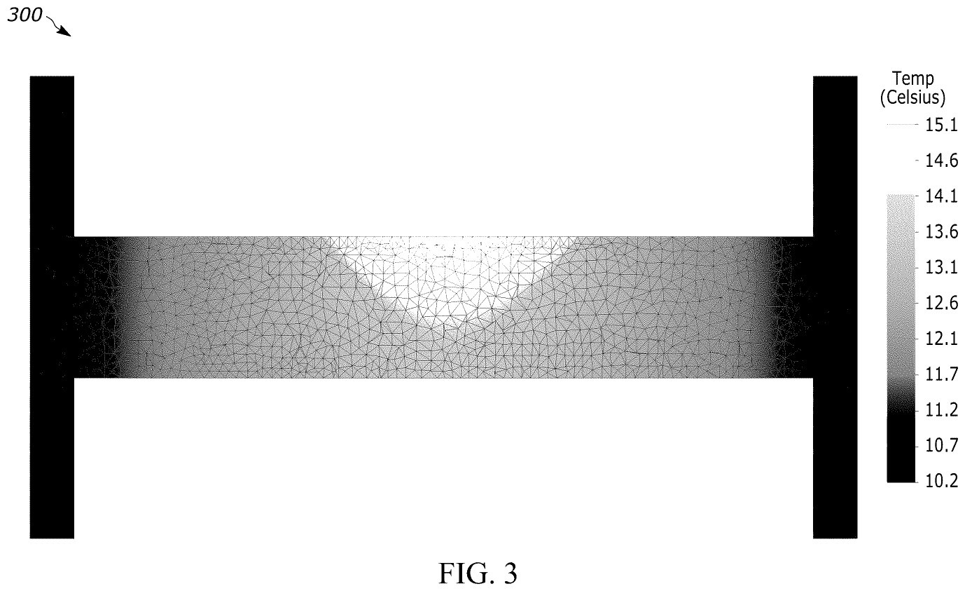

FIG. 2 illustrates a side view of a bi-directional heat transfer apparatus 200 in a horizontal linear configuration for controlling the temperature of a device 202 or apparatus according to the present teaching. The device 202 to be cooled is positioned on top of a thermally conductive block. The block forms a heat spreader 204 that includes a thermally conductive device platform to mount the device 202 to be temperature controlled. The heat spreader 204 can, for example, be aluminum, copper, or some hybrid of both. Numerous other types of high thermal conductivity materials that are formed of metals, composite materials, and/or matrix metal composite materials can be used. For example, a matrix metal composite material can be chosen to have a thermal expansion coefficient that closely matches the device 202. FIG. 3 below shows thermal data 300 for one specific embodiment of a thermally conductive block comprising copper according to the present teaching.

A thermal interface material 206 is positioned between the device 202 and the heat spreader 204. Importantly, the thermal interface material 206 has a relatively low thermal contact resistance and low thermal resistance. The thermal interface material 206 can, for example, be in the form of a thermal paste or grease, which has high thermal conductivity and can also serve to eliminate air gaps and improve heat conduction. The consistency of the thermal interface material 206 can be such that when the material is squeezed between two surfaces, it enhances the flow of heat from a first surface to a second surface. This can be accomplished by filling a void, which usually requires a ductile or malleable material. For example, this can be a solid, or, in some cases, a paste filled with thermally conductive material or an adhesive filled with thermally conductive material.

In one embodiment, the thermal interface material 206 is thin indium foil, for example, 3-mil-thick indium foil. In yet another embodiment, thermal interface material 206 is a structure known as a Heat Spring®, which is manufactured by the Indium Corporation. For example, a 3-mil-thick indium Heat Spring device has a thermal R value of about 0.02cm²-K/W grid at about 150 PSI of compression.

In one embodiment of the present teaching, the thermal interface material 206 is an indium metal alloy that is configured in a “waffle” pattern on the surfaces. The “waffle” pattern configuration is advantageous because it encourages gap-filling and collapsing of the gaps. Indium metal alloys have a distinctive areal thermal resistance that drops dramatically with contact pressure. Areal thermal resistance as described herein is the ratio of the temperature difference between the two faces of a material to the rate of heat flow per unit area. In another embodiment, the thermal interface material 206 is graphene-based. Graphene-based materials are advantageous because the radial heat flow can be higher than the axial heat flow.

For lasers and other optical devices, it is sometimes desirable for the thermal interface material 206 to be a metallic compound or carbon compound. These materials are desirable because they are typically not volatile so they do not outgas in a way that accumulates material on optical elements. Deposits on optical elements often reduce performance due to changes in reflection or transmission. Such deposits also tend to reduce usable lifetime.

In some embodiments, thermal insulation 208 surrounds the device 202 to be cooled. The thermal insulation 208 surrounding the device 202 reduces convective heating of the device 202 from the heat spreader 204 and the ambient surroundings during some operating conditions. A plastic enclosure 210 can be positioned around the thermal insulation 208 to encapsulate the thermal insulation 208.

A first thermoelectric cooler 212 is mounted in thermal contact with a first surface 204′ of the heat spreader 204, through thermal interface material 205. This thermal interface material 205 needs to provide low thermal resistance. This thermal interface material 205 can be the same or can be a different material as thermal interface material 206. In the embodiment shown in FIG. 2, the first thermoelectric cooler 212 is positioned at a first end in the horizontal linear configuration. A first fan-cooled heat sink 214 is mounted in thermal contact with the first thermoelectric cooler 212 through thermal interface material 205. The first fan-cooled heat sink 214 is configured to remove heat in a first direction by convection cooling.

A second thermoelectric cooler 216 is mounted in thermal contact with a second surface 204″ of the heat spreader 204 through thermal interface material 205. In the embodiment shown in FIG. 2, the second thermoelectric cooler 216 is positioned at a second end in the horizontal linear configuration. A second fan-cooled heat sink 218 is mounted in thermal contact with the second thermoelectric cooler 216 through thermal interface material 205. In various embodiments, the same or different thermal interface materials may be used in each location of thermal interface materials 205, 206. The second fan-cooled heat sink 218 is configured to remove heat in a second direction by convection cooling. The second direction can be the same or different from the first direction. The horizontal linear configuration is just one example and does not limit the present teaching in any way. The first and second thermoelectric coolers 212, 216 and the corresponding first and second fan-cooled heat sinks 214, 218 can be mounted in various orientations.

In operation, heat is transferred from the heat spreader 204, which spreads the heat to the first and second thermoelectric coolers 212, 216, from the device 202 by conduction through the thermal interface materials 205, 206. The first and second thermoelectric coolers 212, 216 establish a temperature difference at the device 202 that is cooled by respective ones of the first and second fan-cooled heat sink 214, 218 that are mounted in thermal contact with respective ones of the first and second thermoelectric cooler 212, 216. Heat dissipates from the first and second fan cooled heat sink 214, 218 into the surrounding air by active convection. Air can flow either into and/or out of the first and second fan-cooled heat sinks 214, 218. The direction of air flow through the first and second fan-cooled heat sinks 214, 218 can be the same or opposite. The direction and flow rate of the air depends on the particular heat load. However, in some reductions to practice, better heat removal performance is provided with air flowing into both the first and second fan-cooled heat sinks 214, 218.

The configuration shown in FIG. 2 is advantageous because it separates the cold region from the hot region in the bi-directional heat transfer apparatus and provides substantial thermal insulation for the cold region. In addition, the configuration shown in FIG. 2 is advantageous because it increases the length of heat leakage paths from the hot side of the first and second thermoelectric coolers 212, 216 to the device 202. Thus, one aspect of the present teaching is that there is a separation of heated regions from cooled regions, which reduces convection transfer from hot regions to cold regions, while allowing much more surface area and volume for thermally insulating material, for example, thermal insulation 208.

In a reduction to practice, the first and second thermoelectric coolers 212, 216 each had a rectangular configuration with dimensions of 40 mm×40 mm (total area of 1,600 mm²). One layer of thermal interface material was used between the heat spreader 204 and each of the first and second thermoelectric coolers 212, 216. The Rₜₕₑᵣₘₐₗ was calculated to be in the range of 1.0×10⁻³ K/W to 4.0×10⁻³ K/W. In this configuration, each layer of thermal interface material passed 30W of heat and could produce a temperature difference (ΔT) across each thermal interface of between 0.03 K and 0.12 K.

A reduction to practice of the heat sink configuration of the heat transfer apparatus 200 shown in FIG. 2 has demonstrated the removal of 60 W of heat from a semiconductor laser operating at 13.4 °C in an ambient 40 °C environment, while dissipating 198 watts of electrical power in the thermoelectric coolers. By providing more room for cold-side insulation and removing waste heat power in multiple directions, a relatively high temperature difference between the hot and cold sides at elevated room temperature was achieved, even with 60W of waste heat. This is at least in part because, as compared, for example, to the known heat transfer apparatus 100 of FIG. 1, the horizontal linear configuration heat transfer apparatus 200 is not limited to mounting coolers 108, 110 to just one surface 104″ of the heat spreader that is below the device 102, as it is in heat transfer apparatus 100 of FIG. 1.

FIG. 3 illustrates the results of a finite-element analysis of the temperature gradient as a function of distance into a copper heat spreader during the operation of a laser as it is cooled by the heat transfer apparatus 200 described in connection with FIG. 2. The temperature gradient values 300 illustrate relatively high temperatures proximate to the laser with temperatures lowering as a function of distance in the vertical and horizontal directions as heat is transferred in the heat spreader by conduction, then active removal by the TECs, and then by active convection in the first and second fan cooled heat sinks 214, 218 of the heat transfer apparatus 200.

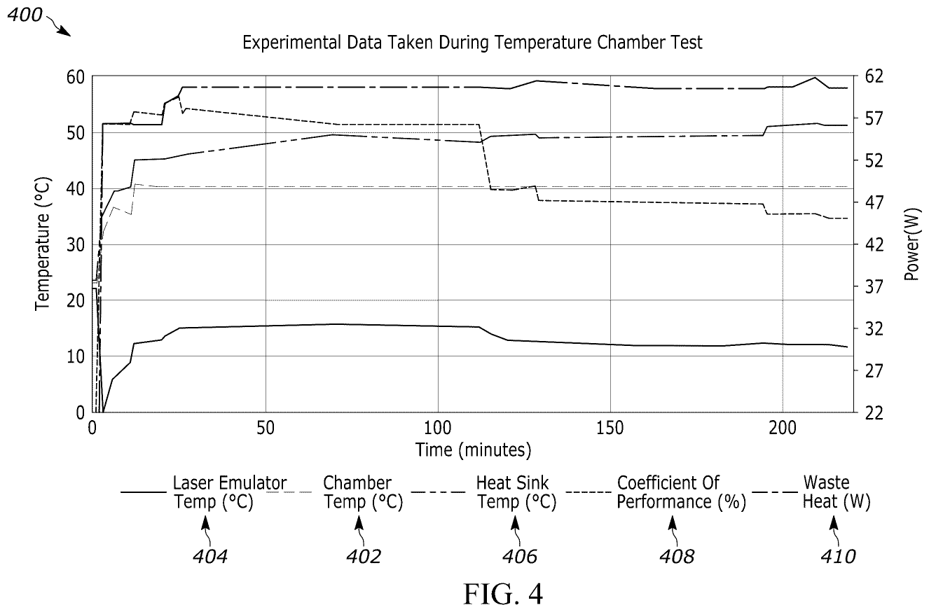

FIG. 4 illustrates experimental thermal performance data 400 taken for the bi-directional heat transfer apparatus described in connection with FIG. 2 with a laser device emulator, serving in place of the laser device 202, and operating during a testing period. The means of simulating waste heat from a laser device was to insert a cartridge heater, whose voltage and current were measured, into a copper block of similar form factor to the actual laser device. Thus, we were able to precisely calculate the actual heat power delivered.

Referring to both FIGS. 2 and 4, the thermal performance data 400 includes test chamber temperature data 402 in degrees C, which indicates that the test chamber is essentially at a constant temperature during the testing period of more than 200 minutes after an initial startup time period of about 25 minutes. The laser device emulator operating temperature data 404 in degrees C is presented as a function of time during the testing period and indicates that the operating temperature of the laser device emulator is relatively constant in the test chamber over the 200-plus-minute testing time period with some decrease in temperature towards the end of the testing time period and no indication of thermal runaway.

The thermal performance data 400 also includes heat sink temperature data 406 in degrees C of the thermally conductive block 204. The heat sink temperature data 406 indicates a relatively constant heat sink temperature over the 200-minute-plus testing time period after the initial startup period. The thermal performance data 400 also includes the coefficient of performance data 408, which is the ratio of the amount of power being dissipated in the form of heat to the power dissipated in the first and second thermoelectric coolers 214, 218 presented as a percentage. In addition, the thermal performance data 400 includes waste heat data 410 in Watts.

For example, at 100 minutes, which is about half way through the testing period, the testing chamber temperature is at a constant 40 degrees C, the laser device emulator is stable and operating at a temperature that is about 15 degrees C with a waste heat load of about 60 W. Under these operating conditions at 100 minutes, the heat spreader 204 temperature is about 48 degrees C.

One aspect of the multi-directional heat transfer apparatus of the present teaching is that the configuration is not limited to the linear configuration described in connection with FIG. 2. The multi-directional heat transfer apparatus of the present teaching can include a plurality of thermoelectric coolers mounted in thermal contact with a different surface of the heat spreader and a plurality of fan-cooled heat sinks, where a respective one of the plurality of fan-cooled heat sinks is mounted in thermal contact with a respective one of the plurality of thermoelectric coolers so that each of the respective ones of the plurality of fan-cooled heat sinks remove heat by convection cooling in a respective one of a plurality of different directions.

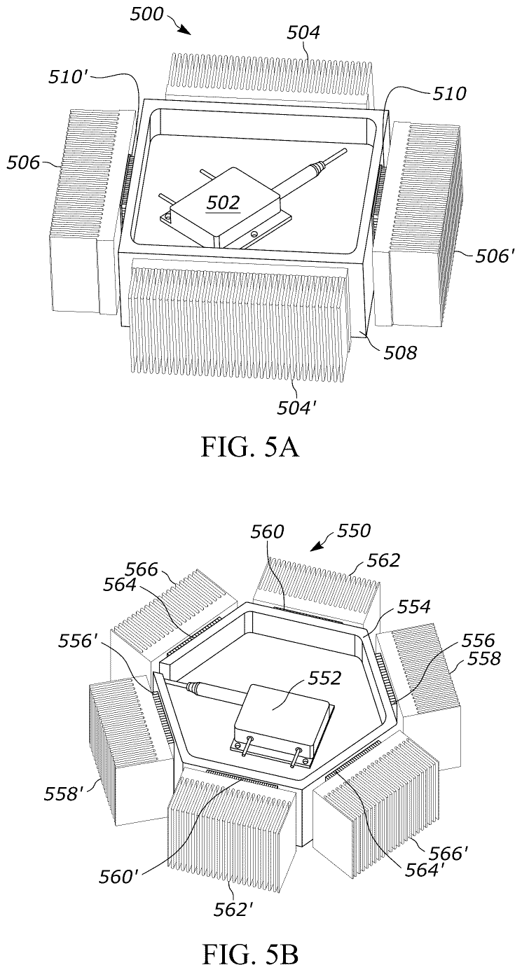

FIG. 5A illustrates a perspective view of a multi-directional heat transfer apparatus 500 according to the present teaching that includes a heat transfer apparatus in both a horizontal linear configuration and in a vertical linear configuration for controlling the temperature of a device 502 or other apparatus according to the present teaching. The multi-directional heat transfer apparatus 500 is similar to the multi-directional heat transfer apparatus 200 that was described in connection with FIG. 2 in that it includes horizontally configured first and second thermoelectric coolers and first and second fan-cooled heat sink 506, 506′.

Additionally, the apparatus 500 includes a vertically positioned linear configuration that includes first and second thermoelectric coolers (not visible in FIG. 5) and first and second fan-cooled heat sink 504, 504′, which can be identical to the horizontal positioned linear configuration. The vertically positioned linear and horizontal positioned linear configurations share a common heat spreader 508 that includes a thermally conductive device platform to mount the device 502 to be temperature controlled and can use the same thermal interface material and method of adhesion. Third and fourth thermoelectric coolers 510, 510′ are attached to fan-cooled heat sink 506, 506′ in a vertical linear configuration. The description of FIG. 2 describes details of the two thermoelectric coolers and respective fan-cooled heat sink that can be used in the configuration of FIG. 5A. The heat transfer apparatus 500 can include some or all of the thermal interface materials 205, 206 of the heat transfer apparatus 200 of FIG. 2A (not specifically shown in FIG. 5. Importantly, the multi-directional heat transfer apparatus 500 with both the vertical and the horizontal linear heat transfer apparatus configurations transfers heat away from the device 502 to be cooled in four different directions, which can greatly increase cooling efficiency of the device 502.

FIG. 5B illustrates a perspective view of a multi-directional heat transfer apparatus 550 according to the present teaching that includes linear heat transfer apparatus arranged in an octagonal configuration for controlling the temperature of a device 552 or apparatus according to the present teaching. The multi-directional heat transfer apparatus 550 is similar to the multi-directional heat transfer apparatus 200 that was described in connection with FIG. 2 and similar to the multi-directional heat transfer apparatus 500 that was described in connection with FIG. 5A. However, the apparatus 550 additionally includes a third linear configuration. A common heat spreader 554 has opposing first and second thermoelectric coolers 556, 556′ and respective fan-cooled heat sinks 558, 558′, opposing third and fourth thermoelectric coolers 560, 560′ and respective fan-cooled heat sinks 562, 562′ and opposing fourth and fifth thermoelectric coolers 564, 564′ and respective fan-cooled heat sinks 566, 566′. This configuration of multiple linear heat transfer configurations forms an octagonal shape. Other embodiments can include more linear heat transfers, and they can be attached to a single heat spreader, or to multiple heat spreaders.

All three linear configurations of first and second thermoelectric coolers and first and second fan-cooled heat sink of the heat transfer apparatus 550 share a common heat spreader 554 and can use the same thermal interface material and method of adhesion. The description of FIG. 2 describes details of the first and second thermoelectric coolers and first and second fan-cooled heat sink that can be used in the configuration of FIG. 5B. Importantly, the multi-directional heat transfer apparatus 550 with the three linear configurations of first and second thermoelectric coolers and first and second fan-cooled heat sink transfers heat away from the device 552 to be cooled in six different directions can greatly increase cooling efficiency of the device 552.

It should be understood that the present teachings are not limited to three linear configurations of first and second thermoelectric coolers and first and second fan-cooled heat sink transfers. Any number of linear configurations of first and second thermoelectric coolers and first and second fan-cooled heat sink transfers can be employed. It should also be understood that the present teachings are not limited to linear configurations of thermoelectric coolers and first and second fan-cooled heat sink transfers. A plurality of non-co-linear configurations can be employed to cool the device in a plurality of directions.

### Equivalents

While the Applicant's teaching is described in conjunction with various embodiments, it is not intended that the Applicant's teaching be limited to such embodiments.

On the contrary, the Applicant's teaching encompasses various alternatives, modifications, and equivalents, as will be appreciated by those of skill in the art, which may be made therein without departing from the spirit and scope of the teaching.

1. A heat transfer apparatus comprising:
a) a heat spreader comprising a thermally conductive device platform to mount a device to be temperature controlled;
b) a first thermoelectric cooler mounted in thermal contact with a first surface of the heat spreader;
c) a first fan-cooled heat sink mounted in thermal contact with the first thermoelectric cooler, the first fan-cooled heat sink configured to remove heat in a first direction by convection cooling;
d) a second thermoelectric cooler mounted in thermal contact with a second surface of the heat spreader; and
e) a second fan-cooled heat sink mounted in thermal contact with the second thermoelectric cooler, the second fan-cooled heat sink configured to remove heat in a second direction by convection cooling.

2. The heat transfer apparatus of claim 1, wherein the heat transfer apparatus comprises a heat pipe.

3. The heat transfer apparatus of claim 1, wherein the heat spreader comprises a thermally conductive heat spreading block.

4. The heat transfer apparatus of claim 1, wherein an interface between the heat spreader and at least one of the first and second thermoelectric coolers is configured so that an R value of a thermal contact resistance is in a range of 0.01 to 0.10 cm² K/W.

5. The heat transfer apparatus of claim 1, wherein an interface between the heat spreader and at least one of the first and second thermoelectric coolers is configured so that an R value of a thermal contact resistance is in a range of 10⁻⁶ m² K/W to 10⁰⁵ m² K/W.

6. The heat transfer apparatus of claim 1, wherein a thermal contact resistance between the heat spreader and at least one of the first and second thermoelectric coolers is established with a metallic foil.

7. The heat transfer apparatus of claim 1, wherein a thermal contact resistance between the heat spreader and at least one of the first and second thermoelectric coolers is established with indium.

8. The heat transfer apparatus of claim 1, wherein the first thermoelectric cooler comprises a thermally conductive ceramic material configured to mount to the first surface of the heat spreader.

9. The heat transfer apparatus of claim 1, wherein at least one of the first and second thermoelectric cooler is mounted to a respective one of the first and second surface of the heat spreader with a graphene polymer matrix composite material.

10. The heat transfer apparatus of claim 1, wherein the heat spreader is formed of copper.

11. The heat transfer apparatus of claim 1 wherein the heat spreader comprises a graphene layer positioned adjacent to the device to be cooled.

12. The heat transfer apparatus of claim 1 further comprising insulation surrounding the heat spreader.

13. The heat transfer apparatus of claim 12, wherein the insulation is selected from the group comprising aerogel, polyurethane encapsulated aerogel, and nitrile butadine.

14. The heat transfer apparatus of claim 1, wherein the first thermoelectric cooler is mounted in thermal contact with the first surface of the heat spreader with a low thermal-conductivity material.

15. The heat transfer apparatus of claim 1, wherein the second direction of convection cooling is 90 degrees from the first direction of convection cooling.

16. The heat transfer apparatus of claim 1, wherein at least one of the first and second fan-cooled heat sinks are configured to push air into the heat spreader.

17. The heat transfer apparatus of claim 1, wherein at least one of the first and second fan-cooled heat sink are configured to pull air away from the heat spreader.

18. The heat transfer apparatus of claim 1, wherein the second direction is non-collinear with the first direction.

19. The heat transfer apparatus of claim 1, further comprising thermal insulation surrounding the device to be temperature controlled.

20. A heat transfer apparatus comprising:
a) a heat spreader configured to attach to a device;
b) a plurality of thermoelectric coolers, each of the plurality of thermoelectric coolers being mounted in thermal contact with a different surface of the heat spreader; and
c) a plurality of fan-cooled heat sinks, a respective one of the plurality of fan-cooled heat sinks being mounted in thermal contact with a respective one of the plurality of thermoelectric coolers so that each of the respective ones of the plurality of fan-cooled heat sinks remove heat by convection cooling in a respective one of a plurality of non-collinear directions.

21. A method of cooling a device, the method comprising:
a) mounting a device on a heat spreader;
b) thermoelectrically cooling a first surface of the heat spreader;
c) forced air cooling the thermoelectrically cooled first surface of the heat spreader in a first heat flow direction;
d) thermoelectrically cooling a second surface of the heat spreader; and
e) forced air cooling the thermoelectrically cooled second surface of the heat spreader in a second heat flow direction that is non-collinear with the first heat flow direction.

22. The method of claim 21, wherein the second heat flow direction is 90 degrees from the first heat flow direction. (Withdrawn) The method of claim 21, wherein the forced air cooling at least one of the thermoelectrically cooled first and second surfaces of the heat spreader comprises flowing air into the heat spreader.

24. The method of claim 21, wherein the forced air cooling at least one of the thermoelectrically cooled first and second surfaces of the heat spreader comprises flowing air away from the heat spreader.

25. The method of claim 21, further comprising surrounding the device with thermal insulation.

26. A temperature controlled laser comprising:
a) a laser;
b) a heat spreader positioned in thermal communication with the laser;
c) a first thermoelectric cooler mounted in thermal contact with a first surface of the heat spreader;
d) a first fan-cooled heat sink mounted in thermal contact with the first thermoelectric cooler, the first fan-cooled heat sink configured to remove heat from the laser by convection cooling in a first direction;
e) a second thermoelectric cooler mounted in thermal contact with a second surface of the heat spreader; and
f) a second fan-cooled heat sink mounted in thermal contact with the second thermoelectric cooler, the second fan-cooled heat sink configured to remove heat from the laser by convection cooling in a second direction that is non-collinear with the first direction.

27. The temperature controlled laser of claim 26, wherein the laser comprises a semiconductor laser.

28. The temperature controlled laser of claim 26, wherein the laser comprises a fiber coupled diode laser.

29. The temperature controlled laser of claim 26, wherein the first and second fan-cooled heat sink are configured so that the second direction is 90 degrees from the first direction.

30. The temperature controlled laser of claim 26, wherein the second surface of the heat spreader is opposite to the first surface of the heat spreader.

31. The temperature controlled laser of claim 26, wherein at least one of the first and second fan-cooled heat sink is configured to push air into the heat spreader.

32. The temperature controlled laser of claim 26, wherein at least one of the first and second fan-cooled heat sink is configured to pull air away from the heat spreader.

33. The temperature controlled laser of claim 26, further comprising thermal insulation surrounding the laser.

34. The temperature controlled laser of claim 26, wherein the laser drives a light source.
